(19) United States
(12) Patent Application Publication
(10) Pub. No.: US 2022/0190222 A1
(43) Pub. Date: Jun. 16, 2022

(54) OPTOELECTRONIC SEMICONDUCTOR DEVICE COMPRISING A DIELECTRIC LAYER AND A TRANSPARENT CONDUCTIVE LAYER AND METHOD FOR MANUFACTURING THE OPTOELECTRONIC SEMICONDUCTOR DEVICE

(71) Applicant: OSRAM Opto Semiconductors GmbH, Regensburg (DE)

(72) Inventor: Ivar Tangring, Regensburg (DE)

(21) Appl. No.: 17/442,648

(22) PCT Filed: Mar. 23, 2020
(86) PCT No.: PCT/EP2020/057988

§ 371 Date: Sep. 24, 2021

(30) Foreign Application Priority Data
Mar. 29, 2019 (DE) 10 2019 108 216.1

(51) Int. Cl. H01L 33/62; H01L 33/48; H01L 33/52; H01L 33/22

(52) U.S. Cl. CPC H01L 33/62; H01L 33/486; H01L 2933/005; H01L 33/22; H01L 2933/0066; H01L 33/52

(57) ABSTRACT

An optoelectronic semiconductor device may include a first semiconductor layer of a first conductivity type and a second semiconductor layer of a second conductivity type, a dielectric layer, and a transparent conductive layer. The first and second semiconductor layers may be stacked one on top of the other to form a layer stack, and a first main surface of the first semiconductor layer may be roughened. The dielectric layer may be arranged over the first main surface of the first semiconductor layer and may have a planar first main surface on a side facing away from the first semiconductor layer. The transparent conductive layer may be arranged over the side of the dielectric layer facing away from the first semiconductor layer.

### CROSS-REFERENCE TO RELATED APPLICATIONS

The present application is a national stage entry according to 35 U.S.C. § 371 of PCT Application No. PCT/EP2020/057988 filed on Mar. 23, 2020; which claims priority to German Patent Application Serial No. 10 2019 108 216.1 filed on Mar. 29, 2019; all of which are incorporated herein by reference in their entirety and for all purposes.

### TECHNICAL FIELD

The present disclosure relates to an optoelectronic semiconductor device comprising a dielectric layer and a transparent conductive layer and further relates to a method for manufacturing the optoelectronic semiconductor layer.

### BACKGROUND

A light emitting diode (LED) is a light emitting device based on semiconductor materials. An LED typically comprises differently doped semiconductor layers and an active zone. When electrons and holes recombine with one another in the region of the active zone, due, for example, to a corresponding voltage being applied, electromagnetic radiation is generated.

In general, concepts are being sought by means of which improved charge carrier injection into the active zone may be effected.

An objective is to provide an improved optoelectronic semiconductor device and an improved method for manufacturing an optoelectronic semiconductor device.

### SUMMARY

An optoelectronic semiconductor device comprises a first semiconductor layer of a first conductivity type and a second semiconductor layer of a second conductivity type, a dielectric layer, and a transparent conductive layer. The first and second semiconductor layers are stacked one on top of the other to form a layer stack, and a first main surface of the first semiconductor layer is roughened. The dielectric layer is arranged over the first main surface of the first semiconductor layer and has a planar first main surface on a side facing away from the first semiconductor layer. The transparent conductive layer is arranged over the side of the dielectric layer facing away from the first semiconductor layer. The planar first main surface is a horizontal surface, i.e., a surface perpendicular to a growth direction of the semiconductor layers. The combination of the dielectric layer being arranged over the roughened first main surface of the first semiconductor layer and comprising a planar first horizontal main surface on the side facing away from the first semiconductor layer enables a high proportion of light beams which would otherwise be reflected at the interface between the transparent conductive layer and an adjacent medium to be reflected already at the interface between the first semiconductor layer and the dielectric layer.

According to embodiments, the dielectric layer completely covers the roughening of the first main surface of the first semiconductor layer. Furthermore, the dielectric layer may be directly adjacent to the first semiconductor layer. The dielectric layer may be directly adjacent to the transparent conductive layer on the side facing away from the first semiconductor layer. This enables an even larger proportion of light beams that would otherwise be reflected at the interface between the transparent conductive layer and an adjacent medium to be reflected at the interface between the first semiconductor layer and the dielectric layer already.

For example, the transparent conductive layer is connected to the first semiconductor layer via contact openings which extend through the dielectric layer.

According to embodiments, the optoelectronic semiconductor device furthermore comprises a first current spreading structure which is connected to the first semiconductor layer. The first current spreading structure may be arranged on a side of the first semiconductor layer facing away from the second semiconductor layer. For example, the first current spreading structure is arranged on a side of the transparent conductive layer facing away from the first semiconductor layer.

The optoelectronic semiconductor device may furthermore comprise a passivation layer on a side of the transparent conductive layer facing away from the first semiconductor layer, the passivation layer being arranged between regions of the first current spreading structure.

For example, the transparent conductive layer has a refractive index n3, and a refractive index n4 of the passivation layer satisfies the following relationship:

n4>0.75*n3.

According to further embodiments, the first current spreading structure may also be arranged on a side of the second semiconductor layer facing away from the first semiconductor layer. For example, the first current spreading structure may be connected to the first semiconductor layer via first contact elements which extend through the first and second semiconductor layers.

The optoelectronic semiconductor device may also comprise a potting compound over the surface of the transparent conductive layer, wherein a refractive index n1 of the dielectric layer and the refractive index n2 of the potting compound satisfy the following relationship: 0.75<n1/n2<1.25. For example, the refractive indices n1 and n2 may satisfy the following relationship: 0.9<n1/n2<1.1. When considering temperature-dependent refractive indices, it is intended that these relationships are satisfied over the entire application temperature. According to further embodiments, n1 may be equal to n2.

A method for manufacturing an optoelectronic semiconductor device comprises forming a semiconductor layer stack comprising a first semiconductor layer of a first conductivity type and a second semiconductor layer of a second conductivity type, roughening a first main surface of the first semiconductor layer and forming a dielectric layer over the first main surface. The method further comprises planarizing a surface of the dielectric layer and forming a transparent conductive layer over the dielectric layer.

The method may further comprise forming contact openings in the dielectric layer before forming the transparent conductive layer.

In addition, the method may comprise forming a first current spreading structure over the transparent conductive layer and forming a passivation layer on a side of the transparent conductive layer facing away from the first semiconductor layer, the passivation layer being formed between regions of the first current spreading structure.

The method may further comprise applying a potting compound over the surface of the transparent conductive layer, a material of the dielectric layer being selected such that a refractive index n1 of the dielectric layer and the refractive index n2 of the potting compound satisfy the following relationship: 0.75<n1/n2<1.25. For example, the refractive indices n1 and n2 may satisfy the following relationship:

0.9<n1/n2<1.1 or n1=n2.

According to further embodiments, an optoelectronic semiconductor device comprises a first semiconductor layer of a first conductivity type and a second semiconductor layer of a second conductivity type, the first and the second semiconductor layers being stacked one on top of the other to form a layer stack, and a first current spreading structure which is connected to the first semiconductor layer and is arranged on a side of the first semiconductor layer facing away from the second semiconductor layer. The optoelectronic semiconductor device further comprises a passivation layer on a side of the first semiconductor layer facing away from the second semiconductor layer, the passivation layer being arranged between regions of the first current spreading structure.

For example, a layer adjacent to the passivation layer has a refractive index n5, and a refractive index n4 of the passivation layer satisfies the following relationship:

n4>0.75*n5.

### BRIEF DESCRIPTION OF THE DRAWINGS

The accompanying drawings serve to provide an understanding of non-limiting embodiments. The drawings illustrate non-limiting embodiments and, together with the description, serve for explanation thereof. Further non-limiting embodiments and many of the intended advantages will become apparent directly from the following detailed description. The elements and structures shown in the drawings are not necessarily shown to scale relative to each other. Like reference numerals refer to like or corresponding elements and structures.

FIG. 1A shows a schematic cross-sectional view of an optoelectronic semiconductor device according to embodiments.

FIG. 1B shows a schematic cross-sectional view of an optoelectronic semiconductor device according to further embodiments.

FIG. 1C shows enlarged cross-sectional views of a detail for explaining a further feature.

FIG. 2A shows a schematic cross-sectional view of an optoelectronic semiconductor device according to further embodiments.

FIG. 2B shows a schematic cross-sectional view of an optoelectronic semiconductor device according to further embodiments.

FIGS. 3A to 3E illustrate schematic cross-sectional views of a workpiece during the manufacture of an optoelectronic semiconductor device.

FIG. 4 shows a schematic cross-sectional view of a workpiece during performance of the method according to further embodiments.

FIGS. 5A to 5F illustrate schematic cross-sectional views of part of a workpiece while further method steps are carried out.

FIGS. 6A to 6C show schematic cross-sectional views of part of a workpiece while the method according to further embodiments is carried out.

FIG. 7A shows a schematic cross-sectional view of the optoelectronic semiconductor device after a further method step has been carried out.

FIG. 7B shows a schematic cross-sectional view of an optoelectronic semiconductor device after a further method step has been carried out.

FIG. 8 outlines a method according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material, for example GaAs, GaN or Si, or of an insulating material, for example sapphire.

Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, AlGaInBN, phosphide semiconductor compounds by means of which, for example, green or longer-wave light may be generated, such as GaAsP, AlGaInP, GaP, AlGaP, and other semiconductor materials such as GaAs, AlGaAs, InGaAs, AlInGaAs, SiC, ZnSe, ZnO, Ga₂O₃, diamond, hexagonal BN and combinations of the materials mentioned. The stoichiometric ratio of the compound semiconductor materials may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical”, as used in this description, is intended to describe an orientation which is essentially perpendicular to the first surface of a substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

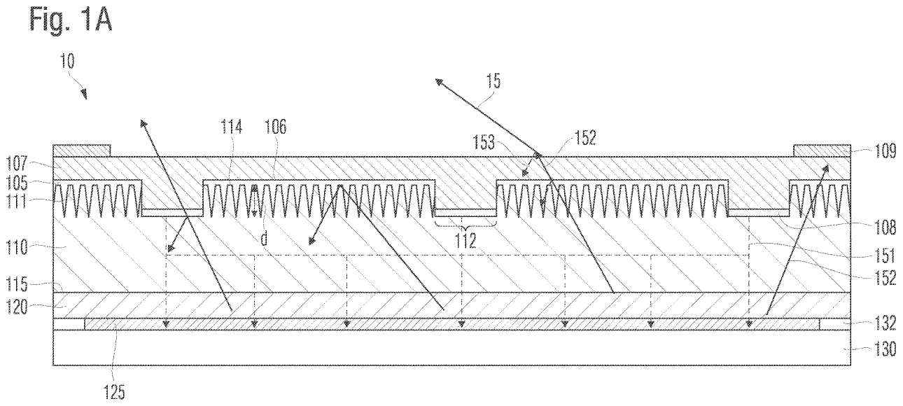

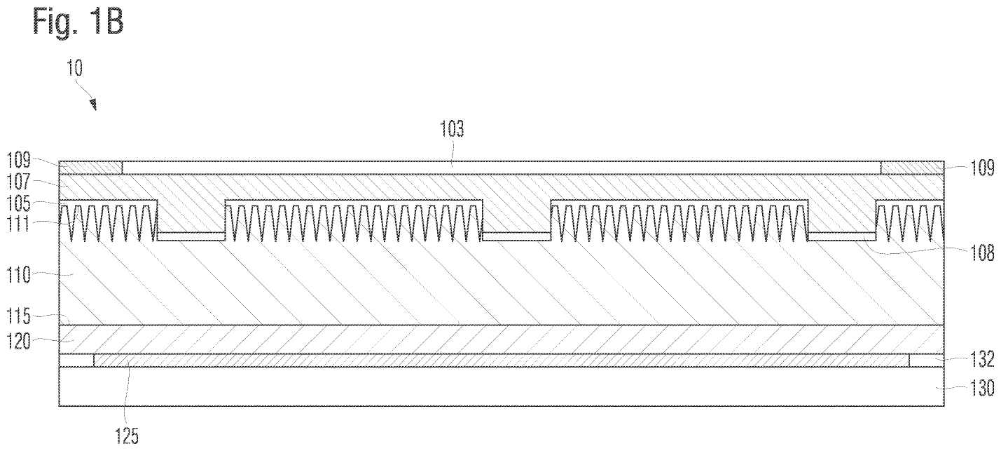

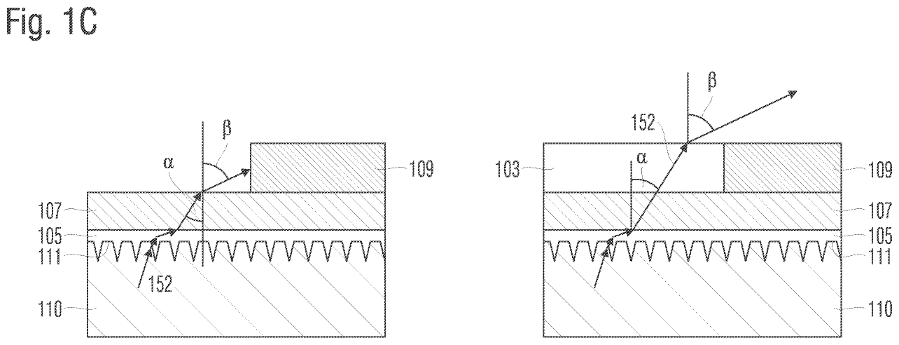

FIG. 1A shows a schematic cross-sectional view of an optoelectronic semiconductor device 10 according to embodiments. The optoelectronic semiconductor device comprises a first semiconductor layer 110 of a first conductivity type, for example n-type, and a second semiconductor layer 120 of a second conductivity type, for example p-type. The first and second semiconductor layers 110, 120 are stacked one on top of the other to form a layer stack. A first main surface 111 of the first semiconductor layer 110 constitutes a light exit surface through which the generated electromagnetic radiation may be coupled out. The first main surface 111 of the first semiconductor layer 110 is roughened. For example, a height d of a protruding region 114, i.e., a distance between the highest elevation and the largest depression, may be in a range from 0.5 to 5 μm. For example, this distance d may be in a range from 1 to 3 μm. A mean distance between two protruding regions 114 may be in a range from 1 to 5 μm. It is to be taken into account here that the roughening is formed in such a way that the protruding regions 114 are each present in two spatial directions, which are for example perpendicular to one another, in a horizontal plane. The shape of the protruding regions 114 may be pyramidal, for example, or may be any other shape. For example, the protruding regions 114 are arranged randomly, avoiding or suppressing the generation of optical modes.

The optoelectronic semiconductor device also comprises a dielectric layer 105. The dielectric layer 105 is arranged over the first main surface 111 of the first semiconductor layer 110 and has a planar first main surface 106 on the side facing away from the first semiconductor layer 110. The dielectric layer 105 thus fills the spaces between adjacent protruding regions 114 in such a way that part of the dielectric layer 105 is arranged even above the protruding regions 114 and forms a planar surface 106. The dielectric layer 105 may be directly adjacent to the first semiconductor layer 110. The optoelectronic semiconductor device 10 furthermore comprises a transparent conductive layer 107 over the side of the dielectric layer 105 facing away from the first semiconductor layer 110. For example, the transparent conductive layer 107 is directly adjacent to the planar first main surface 106 of the dielectric layer 105.

For example, the first and second semiconductor layers 110, 120 may be based on the (In)GaN, (In)Ga(Al)P, (In) (Al)GaAs, or other semiconductor material systems, including, without limitation, those that are used suitable for generating electromagnetic radiation.

An active zone 115 may be arranged between the first semiconductor layer 110 and the second semiconductor layer 120.

The active zone may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these structures.

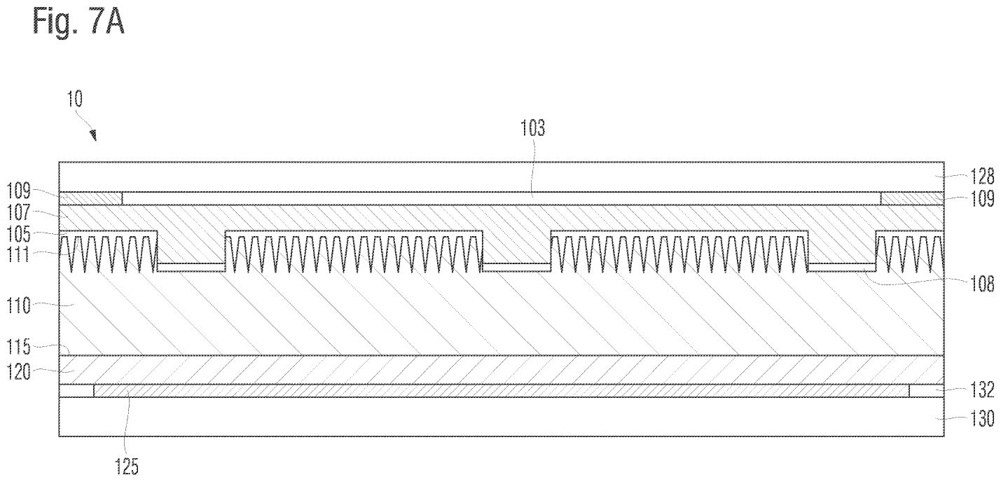

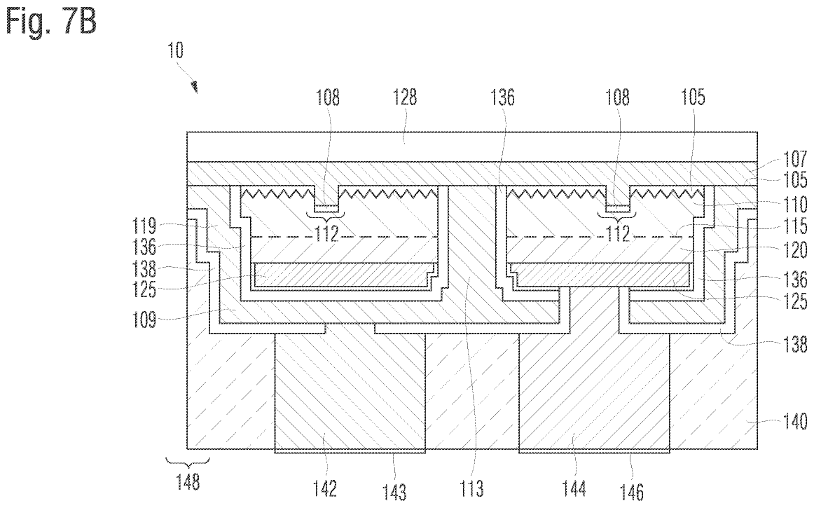

The dielectric layer 105 may contain silicon dioxide, for example. A refractive index of the dielectric layer 105 may be significantly lower than the refractive index of the first semiconductor layer 110. If, for example, the first semiconductor layer 110 is composed of GaN, it has a refractive index of 2.4, for example. In contrast, a dielectric layer 105 made of SiO₂ may have a refractive index of about 1.46. Furthermore, the transparent conductive layer 107 may have a higher refractive index than the dielectric layer 105. The refractive index of the transparent conductive layer 107 may furthermore be between the refractive index of the first semiconductor layer 110 and the refractive index of the dielectric layer 105. For example, the refractive index of the transparent conductive layer may be approximately within a range from 1.8 to 2. According to embodiments, a refractive index of the dielectric layer 105 may be selected such that it is similar or equal to the refractive index of a potting compound (shown in FIG. 7A) that is directly adjacent to the optoelectronic semiconductor device. It is also conceivable that no potting compound is adjacent to the optoelectronic semiconductor device. In this case, for example, the refractive index of the dielectric layer may be as small as possible. For example, if no potting compound is adjacent to the optoelectronic semiconductor device, the refractive index of the dielectric layer may be less than 1.5, for example less than 1.4. In general, a refractive index n1 of the dielectric layer and the refractive index n2 of the potting compound satisfy the following relationship: 0.75<n1/n2<1.25.

FIG. 1A illustrates, by way of example, the effect of the dielectric layer 105 by means of light beams 152 exiting from the first semiconductor layer 110. The presence of the dielectric layer 105 causes only those light beams to be transmitted from the first semiconductor layer 110 into the transparent conductive layer 107 which will not be reflected at the surface of the transparent conductive layer 107 or the interface between the transparent conductive layer 107 and the adjacent medium following in the direction of propagation. More precisely, the dielectric layer 105 causes light beams having an exit angle such that a high proportion of these light beams is reflected at the interface between the transparent conductive layer 107 and the adjacent medium, to be reflected at the interface between the first semiconductor layer 110 and the dielectric layer 105 already. In this way, absorption losses in the transparent conductive layer 107 may be reduced. By means of matching the refractive index of the dielectric layer 105 to the refractive index of a medium that is adjacent to the transparent conductive layer 107, light beams, which would be reflected at the interface between the transparent conductive layer and the adjacent medium due to their exit angle, may be prevented from entering the transparent conductive layer. In this manner, losses, for example through absorption of electromagnetic radiation which has been reflected at the interface between the transparent conductive layer 107 and the adjacent medium, may be avoided.

FIG. 1A shows emitted light beams 152 which are, for example, completely reflected at the interface between the first semiconductor layer 110 and the dielectric layer 105. A portion of further emitted light beams 152 is only reflected at the interface between the dielectric layer 105 and the adjacent transparent conductive layer 107, depending on their exit angle and the ratio of the respective refractive indices. A further portion of the emitted light beams 152 will each be transmitted through the interface. In FIG. 1A it should also be taken into account that the angles at which the light beams exit from the individual layers are not necessarily specified correctly and that, depending on the refractive indices of the respective layers, the light beams shown may be refracted to a greater or lesser extent.

Generally, the presence of the transparent conductive layer 107 may effect improved current injection. Due to the presence of the specially formed dielectric layer 105 between the first semiconductor layer 110 and the transparent conductive layer 107, absorption losses in the transparent conductive layer 107 may be reduced. The improved current injection results in a lower forward voltage and in higher efficiency. Furthermore, there is a more homogeneous current distribution and therefore higher quantum efficiency in generating the electromagnetic radiation. These effects also reduce the generation of heat inside the chip, resulting in a lower temperature inside the chip, which in turn further enhances the positive effects mentioned.

The transparent conductive layer 107 is locally connected to the first semiconductor layer 110 via first contact regions 108. For example, contact openings 112 may be formed in the dielectric layer 106, via which the transparent conductive material 107 is locally connected to the first semiconductor layer 110 via first contact regions 108. The contact openings 112 partially extend through the first semiconductor layer 110.

FIG. 1A also shows current paths 151, via which charge carriers may be respectively injected into the active zone 115. The combination of the transparent conductive layer 107 and the first contact regions 108 may effect particularly uniform current injection. For example, the first contact regions 108 may occupy a surface area of less than 5% of the chip surface. For example, the first contact regions 108 may occupy less than 1% of the chip surface. The first contact regions 108 may, for example, have a diameter of less than 10 μm, for example less than 4 μm. The distance between adjacent first contact regions 108 may, for example, be less than 100 μm, for example approximately 50 μm.

A material of the transparent conductive layer 107 may, for example, be a transparent conductive oxide (“TCO, transparent conductive oxide”), for example indium tin oxide (“ITO”), indium zinc oxide (IZO) or zinc oxide (ZnO). For example, a layer thickness of the transparent conductive layer 107 may be less than 500 nm.

As shown in FIG. 1A, a second contact layer 125 is arranged in contact with the second semiconductor layer 120. A material of the second contact layer 125 may comprise silver, for example. The optoelectronic semiconductor device may be mounted on a carrier 130. Furthermore a dielectric encapsulation 132 may enclose the second contact layer 125.

According to embodiments illustrated in FIG. 1A, a first current spreading structure 109 may be arranged over a surface of the transparent conductive layer 107. The current may be impressed into the transparent conductive layer 107 via the first current spreading structure 109. According to the embodiments shown in FIG. 1A, the first current spreading structure 109 is arranged on a surface of the first semiconductor layer 110 facing away from the second semiconductor layer 120. The first current spreading structure 109 is thus arranged on the light exit side of the optoelectronic semiconductor device 10. Owing to the improved current distribution caused by the transparent conductive layer 107, a lateral expansion of the first current spreading structure 109 may be reduced. This further reduces absorption losses.

Furthermore, the presence of the dielectric layer 105 between the first current spreading structure 109 and the first semiconductor layer 110 helps to reduce the absorption of generated electromagnetic radiation by the first current spreading structure 109. This is due to the fact that only electromagnetic radiation which has been transmitted through the dielectric layer 105 may be absorbed by the first current spreading structure 109. Because of this filtering capacity of the dielectric layer 105, that portion of the radiation that is not absorbed by the first current spreading structure 109, definitely leaves the optoelectronic semiconductor device. As a result, an absorption coefficient of the first current spreading structure 109 is, for example, proportional to the surface area of the first current spreading structure 109.

In comparison to an arrangement in which the first current spreading structure 109 is directly adjacent to the first semiconductor layer 110 and therefore no layer with a filtering capacity is arranged between the first semiconductor layer 110 and the current spreading structure 109, the absorption of generated electromagnetic radiation may thus be further reduced. This is due to the fact that, if the first current spreading structure 109 was directly adjacent to the first semiconductor layer 110, that portion of the radiation that is not absorbed by the current spreading structure 109 and is reflected back into the semiconductor stack would be increased, thereby increasing the probability of absorption.

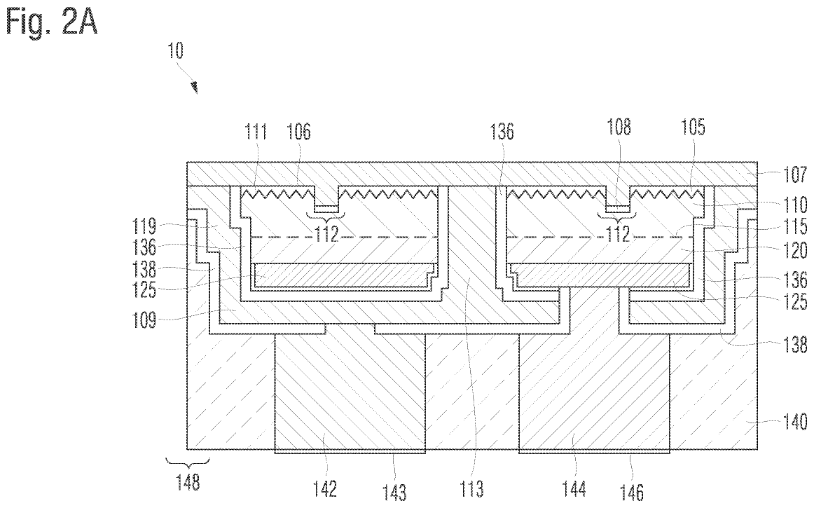

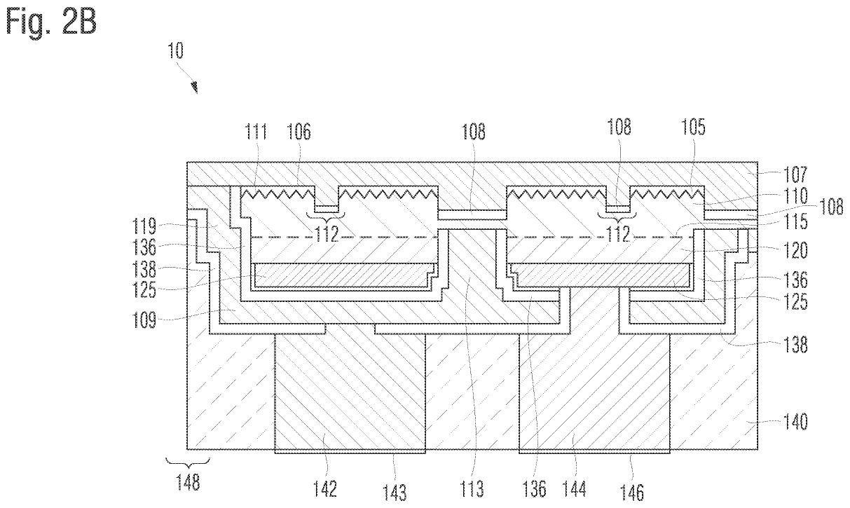

According to further embodiments which are shown for example in FIG. 2A or 2B, the first current spreading structure 109 may, however, be arranged on a side of the second semiconductor layer 120 facing away from the first semiconductor layer 110.

FIG. 1B shows a schematic cross-sectional view of an optoelectronic semiconductor device according to further embodiments. In addition to the components shown in FIG. 1A, the optoelectronic semiconductor device shown in FIG. 1B comprises a passivation layer 103 which is arranged over a main surface of the transparent conductive layer 107 between regions of the first current spreading structure 109. A material of the passivation layer 103 may be selected such that it is essentially free of absorption and has a refractive index n4 which is matched to the refractive index n3 of the transparent conductive layer 107. According to further embodiments, the refractive index of the passivation layer 103 may also be slightly higher than the refractive index of the transparent conductive layer 107. In general, the following relationship may apply:

n4>0.75*n3. For example, the passivation layer may contain undoped zinc oxide.

As will be illustrated below with reference to FIG. 1C, this passivation layer 103 may reduce absorption losses occurring via the first current spreading structure 109. As a result, the layer thickness of the first current spreading structure 109 may be made larger without increasing the absorption. As a result, the area occupation of the first current spreading structure 109 may be reduced in order to achieve a desired amperage. As a result, the efficiency of the device may be further increased. A layer thickness of the first current spreading structure 109 may be greater than 2 μm.

In the left-hand part, FIG. 1C illustrates an emitted light beam in an optoelectronic semiconductor device without a passivation layer. The right-hand part of FIG. 1C illustrates the course of an emitted light beam 152 in an optoelectronic semiconductor device comprising a passivation layer 103. The emitted light beam 152 is refracted at the interface between the first semiconductor layer 110 and the dielectric layer 105 and refracted again at the interface with the transparent conductive layer 107 so that it propagates at an angle α with respect to a surface normal. As shown in the left-hand part of FIG. 1C, it is broken again when exiting from the transparent conductive layer 107, so that it exits at an angle R, which is greater than angle α. As a result, a relatively large proportion of the emitted radiation is absorbed by the first current spreading structure 109.

If, on the other hand, the passivation layer 103 is additionally provided, the refractive index of which is greater than that of air or greater than 1, a smaller proportion of the light beams is refracted in the direction of the first current spreading structures 109. For example, no refraction will ideally occur at the interface between the transparent conductive layer 107 and the passivation layer 103, for example if the passivation layer 103 has the same refractive index as the transparent conductive layer 107. As a result, a light beam 152 is refracted at an angle β only at the transition from the passivation layer to the adjacent medium. At this point, however, the light beam 152 is at the level of the surface of the first current spreading structure 109, so that the light beam is no longer absorbed by the first current spreading structure 109. For example, the passivation layer 103 may have a refractive index greater than 1.3. According to embodiments, the refractive index may be approximately 1.4 or greater, for example greater than 1.8. According to embodiments, the refractive index may be approximately equal to or even greater than that of the transparent conductive layer 107.

Generally, the passivation layer 103 described may be arranged over any light exit surface, however formed, of the optoelectronic semiconductor device, regardless of the presence, for example, of the dielectric layer 105 and the transparent conductive layer 107. Further embodiments thus relate to an optoelectronic semiconductor device which comprises a first semiconductor layer of a first conductivity type and a second semiconductor layer of a second conductivity type. The first and second semiconductor layers are stacked one on top of the other to form a layer stack. The optoelectronic semiconductor device further comprises a first current spreading structure which is connected to the first semiconductor layer and is arranged on a side of the first semiconductor layer facing away from the second semiconductor layer. The optoelectronic semiconductor device further comprises a passivation layer on a side of the first semiconductor layer facing away from the second semiconductor layer, the passivation layer being arranged between regions of the first current spreading structure.

For example, a layer adjacent to the passivation layer has a refractive index n5, and a refractive index n4 of the passivation layer has the following relationship: n4>0.75*n5.

For example, the first semiconductor layer or a transparent conductive layer may be directly adjacent to the passivation layer 103.

As has been described with reference to FIGS. 1A to 1C, the first current spreading structure 109 may be arranged over the light emission surface of the optoelectronic device.

FIG. 2A shows an optoelectronic semiconductor device in which the first current spreading structure 109 is present on a side of the semiconductor layer stack facing away from the light emission surface. As further illustrated in FIG. 2A, the optoelectronic semiconductor device 10 again comprises a first semiconductor layer 110 and a second semiconductor layer 120, which are stacked one on top of the other to form a layer stack. A first main surface 111 of the first semiconductor layer 110 is roughened, in a manner similar to that described with reference to FIGS. 1A to 1C. The optoelectronic semiconductor device comprises a dielectric layer 105 which is arranged over the first main surface 115 of the first semiconductor layer 110 and comprises a planar first main surface 106 on the side facing away from the first semiconductor layer 110. The optoelectronic semiconductor device further comprises a transparent conductive layer 107 over the side of the dielectric layer 105 facing away from the first semiconductor layer 110. The second semiconductor layer 120 is connected to a second contact layer 125. The second contact layer 125 is directly adjacent to a surface of the second semiconductor layer 120 facing away from the first semiconductor layer 110.

The first current spreading structure 109 is arranged on a side of the second semiconductor layer 120 facing away from the first semiconductor layer 110. The first current spreading structure 109 may form, for example, a carrier 119 for the optoelectronic semiconductor device. The first current spreading structure 109 is connected to the transparent conductive layer 107 via a first contact element 113. Furthermore, the transparent conductive layer 107 is connected to the first semiconductor layer 110 via contact openings 112 in the dielectric layer 105. For example, the contact openings 112 may be formed in the dielectric layer 106, via which the transparent conductive material 107 is locally connected to the first semiconductor layer 110 via first contact regions 108. The contact openings 112 extend partially through the first semiconductor layer 110.

According to further embodiments shown in FIG. 2B, the contact elements 113 may be formed such that they establish electrical contact to the first semiconductor layer 110 and are further connected to the first current spreading structure 109. For example, part of the first semiconductor layer 110 may be part of the first contact element 113 in this case. More precisely, in this case the electrical contact is established from the transparent conductive layer 107 to the first current spreading structure 109 via the first contact region and part of the first semiconductor layer 110, if present. The contact openings 112 may be the same or almost the same size as the contact elements 113. According to further embodiments, the size of the contact openings 112 may be different from the size of the contact elements 113. For example, the number of contact openings 112 in the dielectric layer 105 may be greater than the number of contact elements 113. For example, the number of contact openings may be twice as great or greater than the number of contact elements 113.

For example, in the embodiments shown in FIGS. 2A and 2B, the first current spreading structure 109 may be connected to the transparent conductive layer 107 in an edge region 148 of the optoelectronic semiconductor device 10.

FIGS. 2A and 2B further show a potting material 140, a first connecting element 142, a first connecting pad 143, a second connecting element 144, and a second connecting pad 146.

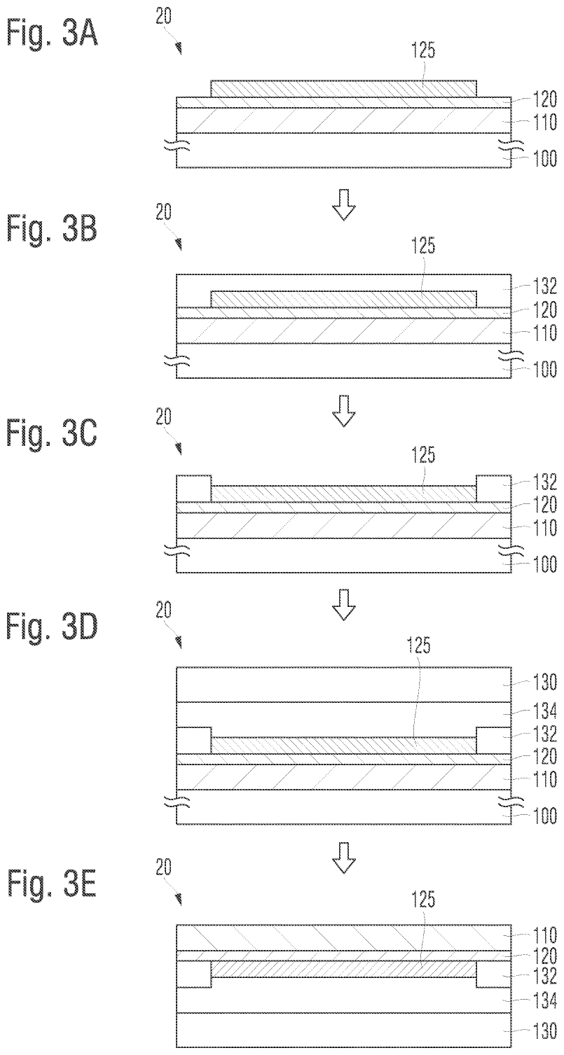

A method for manufacturing an optoelectronic semiconductor device according to embodiments will be described below. FIG. 3A shows a vertical cross-sectional view of a workpiece 20. A semiconductor layer stack is epitaxially grown over a growth substrate 100, for example a sapphire substrate. The semiconductor layer stack comprises, for example, a first semiconductor layer 110 of a first conductivity type, for example n-type, and a second semiconductor layer of a second conductivity type, for example p-type. An active zone (not shown in FIG. 3A) may be arranged between the first and the second semiconductor layers 110, 120. A second contact layer 125 is formed over the second semiconductor layer 120. For example, the second contact layer 125 may contain silver. For example, the second contact layer 125 may be patterned so that it covers only part of the surface of the second semiconductor layer 120.

Then, as shown in FIG. 3B, a dielectric encapsulation 132 is formed over the second contact layer 125. For example, the dielectric encapsulation 132 may comprise one or more dielectric layers. For example, the dielectric encapsulation 132 may be suitable for protecting the second contact layer 125 from environmental or moisture influences.

The encapsulation 132 may then be patterned as illustrated in FIG. 3C. For example, a surface of the second contact layer 125 may be uncovered as a result. Subsequently, for example, a carrier 130 may be applied over the workpiece. For example, the carrier may be a silicon wafer and may be applied over the second contact layer 125 using a suitable solder material 134.

FIG. 3D shows an example of a resulting workpiece 20. The growth substrate 100 may then be removed, for example using a laser lift-off process. The workpiece 20 is turned over so that the first semiconductor layer 110 forms the uppermost surface as a result. FIG. 3E shows an example of a resulting workpiece 20.

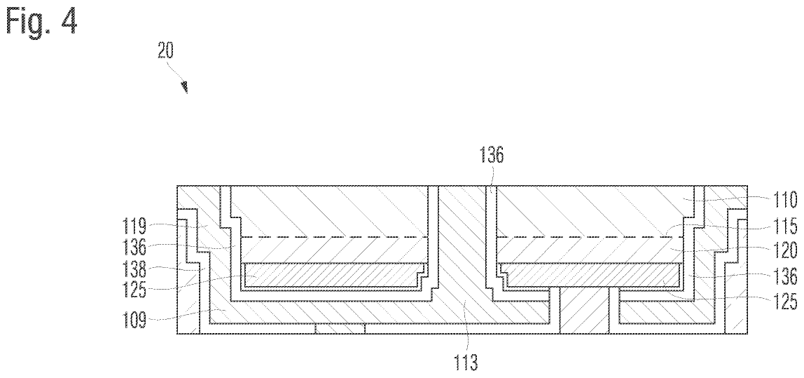

FIG. 4 shows an example of a workpiece 20 for manufacturing the optoelectronic semiconductor device shown, for example, in FIG. 2A. In this case, the carrier is composed of the material of the first current spreading structure 109. Regardless of the exact nature of the workpiece 20, a first surface 110 exists as the main surface to be machined. First contact elements 113 are arranged in order to connect the first current spreading structure 109 to the surface of the workpiece 20. For example, the conductive material of the first current spreading structure 109 may be exposed in an edge region of the optoelectronic semiconductor device on a first surface or may be covered by an insulating material.

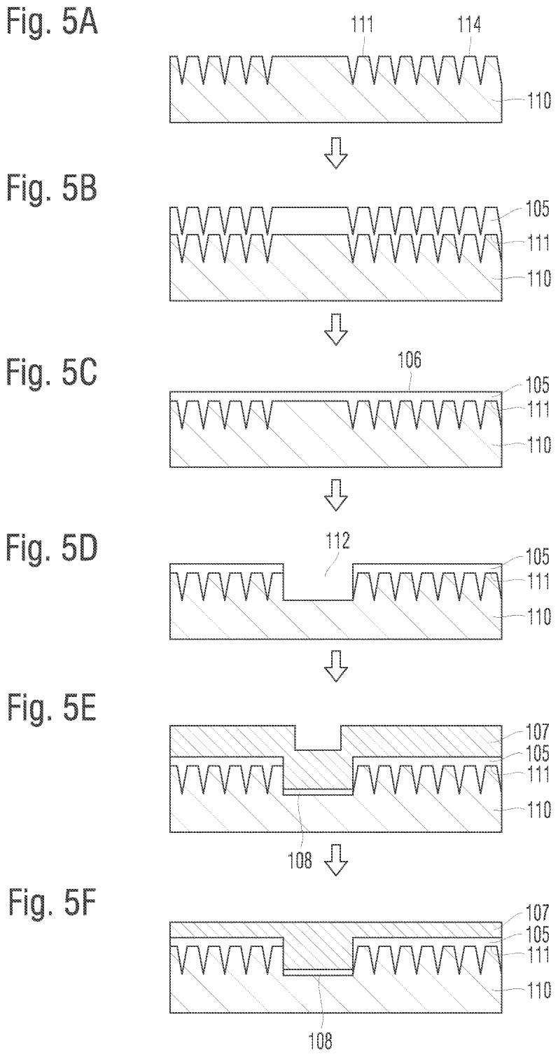

Starting from the structure shown in FIG. 3E or 4, a process for roughening the first main surface 111 of the first semiconductor layer 110 is then carried out. According to embodiments, the roughening may be carried out, for example, by etching the surface with KOH or by structured etching using a photoresist mask. According to embodiments, the process may be carried out in such a way that the surface 111 of the first semiconductor layer 110 is not roughened in regions in which contact openings 112 are to be formed later. As a result, the surface 111 has protruding regions 114, as shown in FIG. 5A.

Then, as illustrated in FIG. 5B, a dielectric layer 105 is applied. For example, the layer 105 may be applied conformally or in a leveling manner.

Subsequently, as shown in FIG. 5C, the dielectric layer 105 is ground back such that part of the dielectric layer 105 remains above the protruding regions 114 of the first semiconductor layer 110. For example, a layer thickness of the dielectric layer 105 remaining over the protruding regions 114 may be more than 100 nm. According to embodiments, the layer thickness may be smaller than 1 μm. For example, a planar surface 106 of the dielectric layer 105 may be produced by a CMP (“chemical mechanical polishing”) process.

Contact openings 112 are then formed in the composite of first semiconductor layer 110 and dielectric layer 105, as shown in FIG. 5D. This may be done, for example, by patterning a photolithographic mask and a subsequent etching step which etches the dielectric layer 105 and a part of the first semiconductor layer 110. Then, if necessary, the first contact region 108 may be formed. For example, a special contact material may be formed in the contact area 108. Examples of a suitable contact material include, for example, silver or gold or zinc oxide. According to further embodiments, the first contact region 108 may also be formed by forming the transparent conductive layer 107. For example, process parameters other than those used in forming the transparent conductive layer 107 may be used to form the first contact region. The transparent conductive layer 107 is then formed in such a way that it covers the surface of the dielectric layer 105, as shown in FIG. 5E.

This is followed by grinding back, for example using a CMP process as shown in FIG. 5F.

The contact openings 112 and, if necessary, the first contact regions 108 are placed such that they provide contact to the first semiconductor layer.

If the workpiece 20 shown in FIG. 4 is machined, additional contact openings 112 are formed in such a way that they also contact the first contact elements 113. The first contact elements 113 penetrate the first and second semiconductor layers 110, 120 and establish contact to the first current spreading structure 109. If necessary, the first contact elements 113 may be omitted, so that the transparent conductive layer 107 is formed exclusively over the edge region of the carrier 119, which, at the same time, constitutes the first current spreading structure 109.

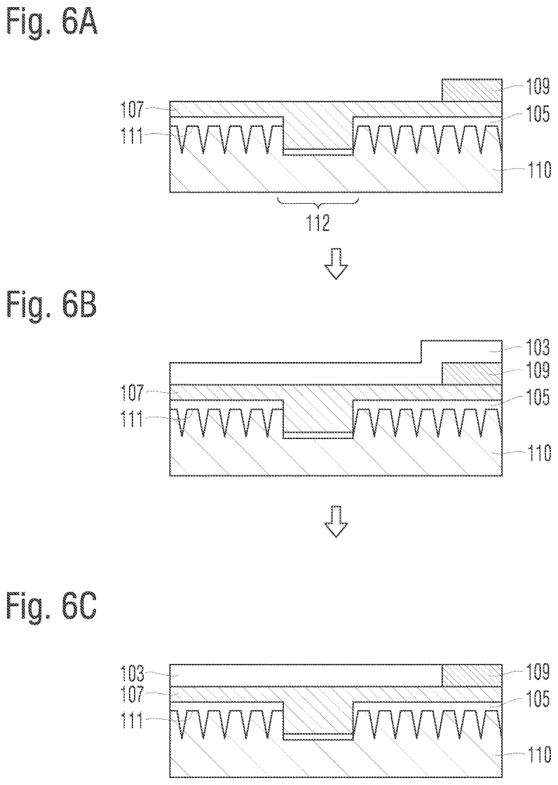

The following FIGS. 6A to 6C illustrate further method steps by which the first current spreading structure 109 is provided over the first main surface 111 of the first semiconductor layer 110 during the manufacture the optoelectronic semiconductor device shown in FIGS. 1A to 1C.

For example, a metal layer may first be applied and patterned. In addition, bond pads may be applied by means of which electrical contact to the first current spreading structure 109 may be effected.

FIG. 6A shows an example of a resulting structure. Next, as described above, a passivation layer 103 is deposited over the entire surface area (FIG. 6B). Thereafter, as shown in FIG. 6C, a planarization step, for example a CMP process, is carried out, thereby obtaining a smooth surface. As a result, part of the surface is covered with the passivation layer 103, and another part is covered with the first current spreading structure 109.

According to embodiments, the semiconductor device 10 may be processed further by additionally applying a potting compound 128 over the surface of the passivation layer 103 or of the transparent conductive layer 107, for example. This is illustrated in FIG. 7A. The potting compound 128 may protect the optoelectronic semiconductor device, for example. According to further embodiments, a converter material may be embedded in the potting compound. According to further embodiments, a converter element may be connected to the passivation layer 103 or the transparent conductive layer 107 through the potting compound 128 or a suitable adhesive. According to embodiments, a refractive index of the potting compound 128 or of the adhesive may be adapted to the refractive index of the dielectric layer 105. For example, a refractive index n1 of the dielectric layer and the refractive index n2 of the potting compound may satisfy the following relationship: 0.75<n1/n2<1.25. The refractive index n1 of the dielectric layer may, for example, be equal to the refractive index n2 of the potting compound. The potting compound may be silicone, for example.

For example, the refractive indices n1 and n2 may satisfy the following relationship: 0.9<n1/n2<1.1. When considering temperature-dependent refractive indices, it is intended that these relationships are satisfied over the entire application temperature. According to further embodiments, n1 may be equal to n2.

In this way it may be ensured that electromagnetic radiation which has exited the semiconductor layer stack and entered the dielectric layer 105 is not reflected at the interface with the potting compound but actually exits. Selecting the refractive indices in this manner may cause the generated electromagnetic radiation to propagate only once through the transparent conductive layer 107, thereby reducing the losses due to absorption. FIG. 7B shows a cross-sectional view of an optoelectronic semiconductor device according to embodiments in which the first current spreading structure 109 is arranged on a surface of the first semiconductor layer 110 facing away from the light exit side. In this case, too, the potting compound 128 is arranged over the surface of the transparent conductive layer 107. For example, the refractive index n2 of the potting compound 128 matches the refractive index n1 of the dielectric layer 105 or satisfies the relationship: 0,75<n1/n2<1.25. As is also shown in FIG. 7B, for example, the first current spreading structure 109 may be connected to the transparent conductive layer 107 in an edge region 148 of the optoelectronic semiconductor device 10.

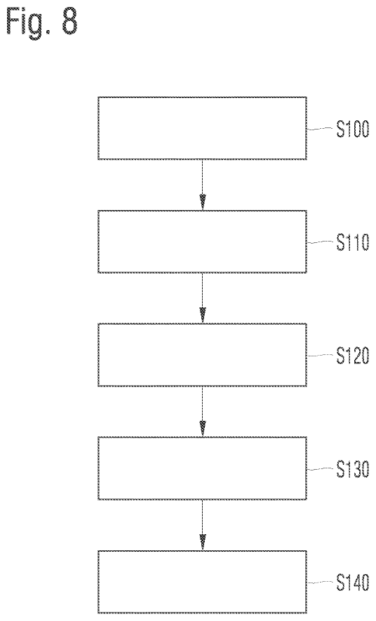

FIG. 8 outlines a method according to embodiments. A method for manufacturing an optoelectronic semiconductor device comprises forming (S100) a semiconductor layer stack comprising a first semiconductor layer of a first conductivity type and a second semiconductor layer of a second conductivity type, and roughening (S110) a first main surface of the first semiconductor layer. The method further comprises forming (S120) a dielectric layer over the first main surface, planarizing (S130) a surface of the dielectric layer, and forming (S140) a transparent conductive layer over the dielectric layer.

As has been described, improved current injection may be achieved while simultaneously reducing absorption losses. Due to the improved power supply, the optoelectronic semiconductor device may be operated at higher powers. In particular according to embodiments shown in FIGS. 1A to 1C, very good thermal connection of the semiconductor device may be achieved at the same time. Accordingly, the optoelectronic semiconductor device may be used in applications including, but not limited to those involving high power, for example more than 3 to 4 W/mm², for example more than 10 W/mm².

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor device
15 emitted electromagnetic radiation
20 workpiece
100 growth substrate
103 passivation layer
105 dielectric layer
106 first main surface of the dielectric layer
107 transparent conductive layer
108 first contact region
109 first current spreading structure
110 first semiconductor layer
111 first main surface of the first semiconductor layer
112 contact opening
113 first contact element
114 protruding region
115 active zone
119 carrier
120 second semiconductor layer
125 second contact layer
128 potting compound
130 carrier
132 dielectric encapsulation
134 solder material
136 first insulating material
138 second insulating material
140 potting material
142 first connecting element
143 first connecting pad
144 second connecting element
146 second connecting pad
148 edge region
151 current path
152 emitted light beam
153 reflected light beam

1. An optoelectronic semiconductor device, comprising:
a first semiconductor layer of a first conductivity type and a second semiconductor layer of a second conductivity type;
a dielectric layer; and
a transparent conductive layer;
wherein the first and second semiconductor layers are stacked one on top of the other to form a layer stack, and wherein a first main surface of the first semiconductor layer is roughened;
wherein the dielectric layer is arranged over the first main surface of the first semiconductor layer and has a planar horizontal first main surface on a side facing away from the first semiconductor layer; and
wherein the transparent conductive layer is arranged over the side of the dielectric layer facing away from the first semiconductor layer, wherein the transparent conductive layer is locally connected to the first semiconductor layer via first contact regions.

2. The optoelectronic semiconductor device according to claim 1, wherein the transparent conductive layer is connected to the first semiconductor layer via contact openings which extend through the dielectric layer.

3. The optoelectronic semiconductor device according to claim 1, further comprising a first current spreading structure connected to the first semiconductor layer.

4. The optoelectronic semiconductor device according to claim 3, wherein the first current spreading structure is arranged on a side of the first semiconductor layer facing away from the second semiconductor layer.

5. The optoelectronic semiconductor device according to claim 4, wherein the first current spreading structure is arranged on a side of the transparent conductive layer facing away from the first semiconductor layer.

6. The optoelectronic semiconductor device according to claim 4, further comprising a passivation layer on a side of the transparent conductive layer facing away from the first semiconductor layer, wherein the passivation layer is arranged between regions of the first current spreading structure.

7. The optoelectronic semiconductor device according to claim 6, wherein the transparent conductive layer has a refractive index n3, and a refractive index n4 of the passivation layer satisfies the following relationship: n4>0.75*n3.

8. The optoelectronic semiconductor device according to claim 3, wherein the first current spreading structure is arranged on a side of the second semiconductor layer facing away from the first semiconductor layer.

9. The optoelectronic semiconductor device according to claim 8, wherein the first current spreading structure is connected to the first semiconductor layer via first contact elements extending through the first and second semiconductor layers.

10. The optoelectronic semiconductor device according to claim 1, further comprising a potting compound over the surface of the transparent conductive layer, wherein a refractive index n1 of the dielectric layer and the refractive index n2 of the potting compound fulfill the following relationship: 0.75<n1/n2<1.25.

11. The optoelectronic semiconductor device according to claim 10, wherein the refractive index n1 of the dielectric layer and the refractive index n2 of the potting compound fulfill the following relationship: 0.9<n1/n2<1.1.

12. A method for manufacturing an optoelectronic semiconductor device, comprising:
forming a semiconductor layer stack comprising a first semiconductor layer of a first conductivity type and a second semiconductor layer of a second conductivity type;
roughening a first main surface of the first semiconductor layer;
forming a dielectric layer over the first main surface;
planarizing a surface of the dielectric layer; and
forming a transparent conductive layer over the dielectric layer, such that the transparent conductive layer covers the surface of the dielectric layer.

13. The method according to claim 12, further comprising forming contact openings in the dielectric layer before forming the transparent conductive layer.

14. The method according to claim 12, further comprising forming a first current spreading structure over the transparent conductive layer and forming a passivation layer on a side of the transparent conductive layer facing away from the first semiconductor layer, wherein the passivation layer is formed between regions of the first current spreading structure.

15. The method according to claim 12, further comprising applying a potting compound over the surface of the transparent conductive layer, wherein a material of the dielectric layer is selected such that a refractive index n1 of the dielectric layer and the refractive index n2 of the potting compound fulfill the following relationship: 0.75<n1/n2<1.25.

16. An optoelectronic semiconductor device, comprising:
a first semiconductor layer of a first conductivity type and a second semiconductor layer of a second conductivity type;
wherein the first and second semiconductor layers are stacked one on top of the other to form a layer stack;
further comprising a first current spreading structure connected to the first semiconductor layer and is arranged on a side of the first semiconductor layer facing away from the second semiconductor layer; and
further comprising a passivation layer on a side of the first semiconductor layer facing away from the second semiconductor layer, wherein the passivation layer is arranged between regions of the first current spreading structure, and wherein the passivation layer and the regions of the first current spreading layer form a planar surface.

17. The optoelectronic semiconductor device according to claim 16, wherein a layer adjacent to the passivation layer has a refractive index n5, and a refractive index n4 of the passivation layer satisfies the following relationship: n4>0.75*n5.
